(19) United States
(12) Patent Application Publication
(10) Pub. No.: US 2006/0037540 A1
(43) Pub. Date: Feb. 23, 2006

(54) Delivery system

(75) Inventors: Egbert Woelk, North Andover, MA (US); Deodatta Vinayak Shenai-Khatkhate, Danvers, MA (US); Ronald L. Dicarlo JR., Danville, NH (US)

Correspondence Address: S. Matthew Cairns;Rohm and Haas Electronic Materials LLC, 455 Forest Street, Marlborough, MA, 01752, US

(73) Assignee: Rohm and Haas Electronic Materials LLC, Marlborough, MA (US)

(21) Appl. No.: 11/191,751

(22) Filed: Jul. 28, 2005

Related U.S. Application Data
(60) Provisional application No. 60/603,478, filed on Aug. 20, 2004.

(51) Int. Cl. C23C 16/00

(52) U.S. Cl. 118/726; 427/250

(57) ABSTRACT

Systems for delivering solid organometallic compounds in the vapor phase to reactors are provided. Such systems include a dual-chambered cylinder design for use with a frit of solid organometallic source material for chemical vapor phase deposition systems, and a method for transporting a carrier gas saturated with the organometallic compound for delivery into such deposition systems.

The present invention relates generally to a vapor generator system for use in vapor deposition equipment. In particular, the present invention relates to a vapor generator system designed for the requirements of vapor phase epitaxy and other chemical vapor deposition equipment.

Group III-V compound semiconductor materials including different monocrystalline layers with varying compositions and with thicknesses typically ranging from fractions of a micron to a few microns are used in the production of many electronic and optoelectronic devices such as lasers and photodetectors. Chemical vapor deposition methods using organometallic compounds are typically employed in the chemical vapor deposition (“CVD”) art for the deposition of metal thin-films or semiconductor thin-films, such as films of Group III-V compounds. Such organometallic compounds (often referred to as “precursors”) may be either liquid or solid.

In CVD methods, a reactive gas stream is typically delivered to a reactor to deposit the desired film. The reactive gas stream is typically composed of a carrier gas, such as hydrogen, loaded with precursor compound vapor. When the precursor compound is a liquid, a reactive gas stream is typically obtained by passing (i.e. bubbling) a carrier gas through the liquid precursor compound in a cylindrical delivery device (i.e. a bubbler). Typically, solid precursors are placed in a cylindrical vessel or container and subjected to a constant temperature to vaporize the solid precursor. A carrier gas is employed to pick up the precursor compound vapor and transport it to a deposition system. Most solid precursors exhibit poor and erratic delivery rates when used in conventional bubbler-type precursor vessels. Such conventional bubbler systems can result in a non-stable, non-uniform flow rate of the precursor vapors, especially when solid organometallic precursor compounds are used. Non-uniform organometallic vapor phase concentrations produce an adverse effect on the compositions of the films, particularly semiconductor films, being grown in metalorganic vapor phase epitaxy (“MOVPE”) reactors.

Other delivery systems have been developed that attempt to address the problems of delivering solid precursor compounds to a reactor. While some of these delivery systems were found to provide a uniform flow rate, they failed to provide a consistently high concentration of precursor material. The inability to achieve a stable supply of feed vapor from solid precursors at a consistently high concentration is problematic to the users of such equipment, particularly in semiconductor device manufacture. The unsteady organometallic precursor flow rate can be due to a variety of factors including progressive reduction in the total surface area of chemical from which evaporation takes place, channeling through the solid precursor compound where the carrier gas has minimal contact with the precursor compound and the sublimation of the precursor solid material to parts of the delivery system where efficient contact with the carrier gas is difficult or impossible.

Channeling is a particular problem in that once a channel forms, the carrier gas follows the channel rather than passing through the solid precursor material. As a result, much solid precursor may remain unused once channeling forms. This adds to the cost of manufacturing because the cylinders need to be replaced more frequently.

Higher carrier gas flow rates give higher transportation rates of organometallic compound to the vapor phase reactor. Such higher flow rates are needed to grow thicker films in less time. For example, in certain applications the growth rate is increasing from 2.5 μm/hour to 10 μm/hour. In general, the use of higher carrier gas flow rates with solid organometallic compounds is unfavorable to maintaining a stable concentration of the organometallic compound in the gas phase as such higher flow rates can lead to an increased rate of channeling.

Attempts have been made to provide consistent concentrations of solid precursor material in the vapor phase. U.S. Pat. No. 4,916,828 discloses a method of producing a saturated vapor of solid metal organic compound using a cylinder containing the solid metal organic compound mixed with a packing material, such as distillation packing material. In practice, such packing material does not necessarily reduce channeling. Further, the amount of solid precursor that can be supplied in a cylinder is reduced as part of the interior volume is consumed by the packing material. Accordingly, this approach does not reduce the number of cylinder changes required.

Conventional cylinder designs fail to provide a uniform flow rate with maximum pick-up of solid precursor material. There remains a continuing need for stable flow/pick-up of solid precursor material vapor with reduced channel formation. Further, there is a need for delivery devices that are tailored to provide a uniform and high concentration of precursor material vapor until total or near total depletion of the precursor material.

It has been found that a cake of solid precursor compound in a cylinder provides a more consistent, stable concentration of precursor compound in the vapor phase and provide for better depletion of the solid precursor compound from the cylinder as compared conventional techniques.

The present invention provides a vapor-phase delivery apparatus for solid organometallic compounds including a dual-chambered vessel having an elongated cylindrical shaped portion having an inner surface, a top closure portion, a bottom closure portion, and inlet and outlet chambers in fluid communication and separated by a porous element, the top closure portion having a fill plug and a gas inlet opening, the fill plug and gas inlet opening communicating with the inlet chamber, an outlet opening communicating with the outlet chamber, the porous element being spaced from the bottom closure portion, the porous element contained in a floor of the inlet chamber, and a frit formed from solid organometallic precursor contained within the inlet chamber.

The present invention further provides a method of forming the above-described vapor phase delivery device including forming a frit of a solid organometallic precursor in a vapor-phase delivery apparatus including the steps of: a) providing a vapor-phase delivery apparatus having a dual-chambered vessel having an elongated cylindrical shaped portion having an inner surface, a top closure portion, a bottom closure portion, and inlet and outlet chambers in fluid communication and separated by a porous element, the top closure portion having a fill plug and a gas inlet opening, the fill plug and gas inlet opening communicating with the inlet chamber, an outlet opening communicating with the outlet chamber, the porous element being spaced from the bottom closure portion, the porous element contained in a floor of the inlet chamber; b) introducing solid organometallic precursor to the vapor-phase delivery apparatus; c) agitating the vapor-phase delivery apparatus to provide the solid organometallic precursor with a level surface; and d) fritting the solid organometallic precursor.

Also provided by the present invention is a method of providing a fluid gas stream including a carrier gas saturated with organometallic compound to a chemical vapor deposition system including the steps of: a) providing the vapor-phase delivery apparatus described above; b) introducing a carrier gas into the inlet chamber through the gas inlet opening; c) flowing the carrier gas at a sufficient flow rate in contact with the source of solid organometallic precursor to substantially saturate the carrier gas with the organometallic precursor; and d) directing the precursor saturated carrier gas to exit the vapor-phase delivery apparatus through the outlet opening.

Further, a method of depositing a metal film is provided including the steps of: a) providing the vapor-phase delivery apparatus described above; b) introducing a carrier gas into the inlet chamber through the gas inlet opening; c) flowing the carrier gas at a sufficient flow rate in contact with the source of solid organometallic precursor to substantially saturate the carrier gas with the organometallic precursor; d) directing the precursor saturated carrier gas to exit the vapor-phase delivery apparatus through the outlet opening; f) delivering the precursor saturated carrier gas to a reaction vessel containing a substrate; and g) subjecting the precursor saturated carrier gas to conditions sufficient to decompose the precursor to form a metal film on the substrate.

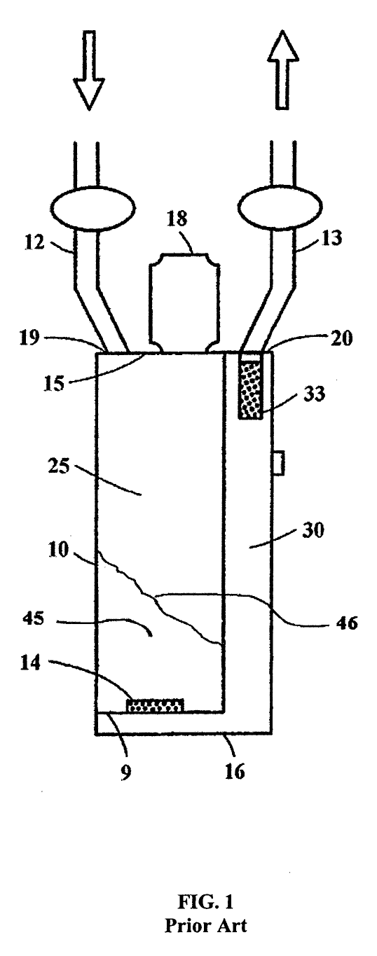

FIG. 1 is a cross-sectional view of a prior art delivery device containing solid organometallic precursor compound.

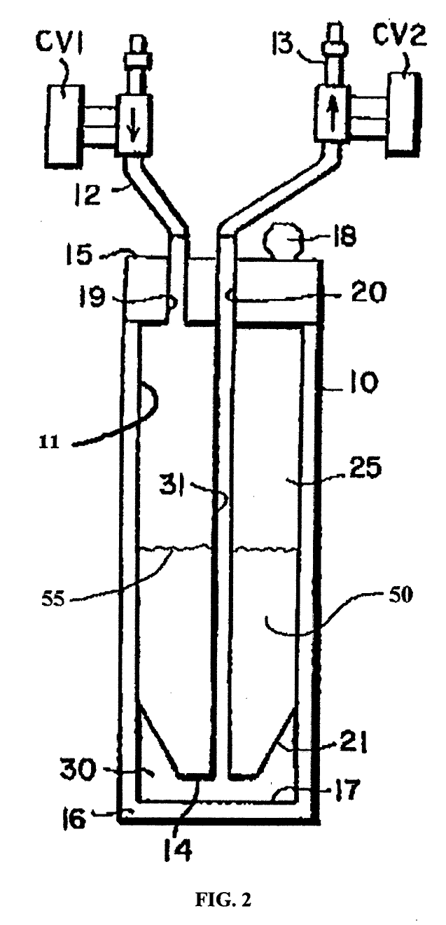

FIG. 2 is a cross-sectional view of a delivery device of the present invention containing solid organometallic precursor compound.

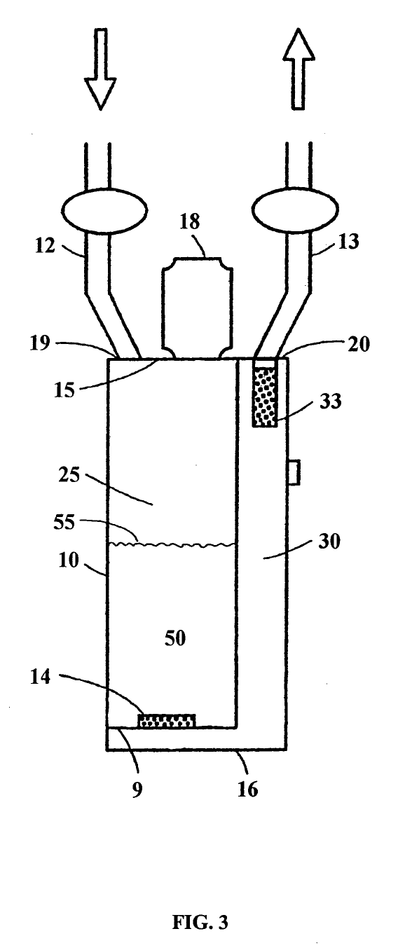

FIG. 3 is a cross-sectional view of a second delivery device of the present invention containing solid organometallic precursor compound.

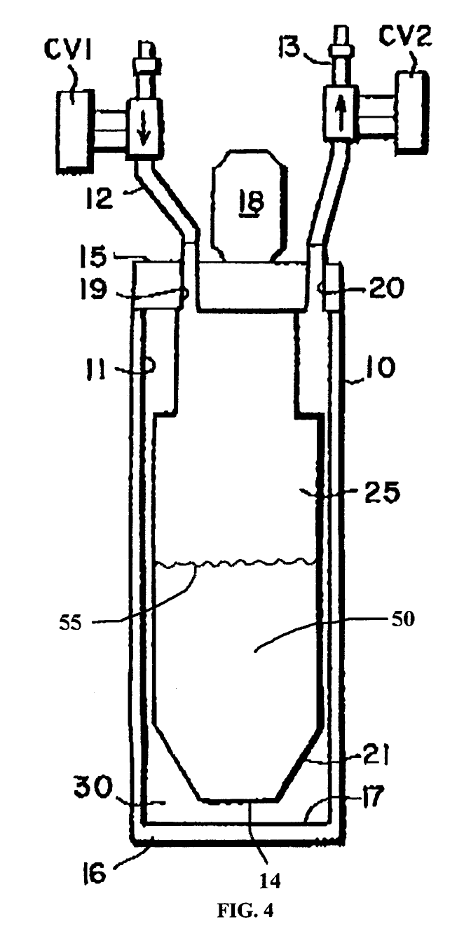

FIG. 4 is a cross-sectional view of a third delivery device of the present invention containing solid organometallic precursor compound

As used throughout this specification, the following abbreviations shall have the following meanings, unless the context clearly indicates otherwise: ° C.=degrees centigrade; sccm=standard cubic centimeter per minute; cm=centimeter; mm=millimeter; μm=micron=micrometer; g=gram; PTFE=polytetrafluoroethylene; and TMI=trimethyl indium.

The indefinite articles “a” and “an” are intended to include both the singular and the plural. “Halogen” refers to fluorine, chlorine, bromine and iodine and “halo” refers to fluoro, chloro, bromo and iodo. Likewise, “halogenated” refers to fluorinated, chlorinated, brominated and iodinated. “Alkyl” includes linear, branched and cyclic alkyl. All numerical ranges are inclusive and combinable in any order except where it is clear that such numerical ranges are constrained to add up to 100%.

The vapor generator or delivery device of the present invention is designed to eliminate poor and erratic delivery rates exhibited by known designs as well as their inability to provide complete or near complete uniform depletion of the solid organometallic precursor material.

The delivery device of the present invention includes a delivery cylinder, the delivery cylinder being a dual-chambered shaped vessel for producing vapors of solid organometallic precursor using a carrier gas. Preferably, such dual-chambered shaped vessel is cylindrically-shaped. Typically, such delivery cylinders have an elongated shaped portion having an inner surface defining a cross-section throughout the length of the cylindrical portion, a top closure portion, a bottom closure portion, and inlet and outlet chambers in fluid communication and separated by a porous element, the top closure portion having a fill plug and a gas inlet opening, the fill plug and gas inlet opening communicating with the inlet chamber, an outlet opening communicating with the outlet chamber, the porous element being spaced from the bottom closure portion, the porous element contained in a floor of the inlet chamber, and a frit formed from solid organometallic precursor contained within the inlet chamber. In one embodiment, the inlet chamber further includes a conical-shaped lower portion which contains the porous element. In another embodiment, the conical-shaped lower portion decreases in cross-section toward the porous element. In yet another embodiment, the porous element forms the floor of the conical-shaped lower portion. In a still further embodiment, the inlet chamber and outlet chamber are concentric. When the inlet and outlet chambers are concentric, the inlet chamber may be contained within the outlet chamber or the outlet chamber may be contained within the inlet chamber. In yet another embodiment, the outlet chamber may contain a second porous element, such as, but not limited to, being located at the outlet opening, such that the gas exits the vessel by passing through the porous element.

These cylinders may be constructed of any suitable material, such as glass, PTFE or metal, as long as the material is inert to the organometallic compound contained therein. Typically, the cylinder is constructed of a metal. Exemplary metals include, without limitation, nickel alloys and stainless steels. Suitable stainless steels include, but are not limited to, 304, 304 L, 316, 316 L, 321, 347 and 430. Suitable nickel alloys include, but are not limited to, INCONEL, MONEL, HASTELLOY and the like. It will be appreciated by those skilled in the art that a mixture of materials may be used in the manufacture of the present cylinders.

Porous elements having a wide variety of porosities may be used in the present invention. The particular porosity will depend upon the a variety of factors well within the ability of one skilled in the art. Typically, the porous element has a pore size of from 0.5 to 100 μm, and more typically from 0.5 to 10 μm. However, porous elements having porosities greater than 100 μm or porosities less than 0.5 μm may be suitable for certain applications. The porous element is typically a frit having a controlled porosity. Any material may be used to construct the porous element provided it is inert to the organometallic compound used under the conditions employed and the desired porosity can be controlled. Suitable materials include, but are not limited to, glass, PTFE or metals such as stainless steels or nickel alloys. Any of the above described stainless steels and nickel alloys may suitably be used. Typically, the porous element is a sintered metal, and more typically stainless steel.

The porous element is generally contained in the floor of the inlet chamber. Such porous element may compose the entire floor of the inlet chamber or a portion of the floor of the inlet chamber. The porous element retains the solid organometallic precursor frit in the inlet chamber.

When the inlet chamber further includes a conical-shaped lower portion, the porous element is contained within such conical-shaped lower portion. Typically, the porous element forms the floor of the conical-shaped lower portion. The combination of the generally conical-shaped lower portion and porous element provides a restriction for the gas flow. This restriction affords uniform carrier gas flow through the solid organometallic precursor frit. The generally conical-shaped lower portion of the inlet chamber may be of any angle, such as from 1 to 89 degrees, as measured from the plane of the floor of the inlet chamber. Typically, the conical section has an angle of 60 degrees or greater.

The size of the porous element is not critical and its dimensions may vary over a wide range. For example, the porous element may be a disk having a diameter of 1 cm (0.4 inches) or greater, such as 1.25 cm (0.5 inches), 1.9 cm (0.75 inches), 2.54 cm (1 inch), 3.8 cm (1.5 inches), 5 cm (2 inches) or even greater. The porous element may have a variety of thicknesses, such as 0.32 cm (0.125 inches) or greater, such as, for example, 0.6 cm (0.25 inches), 1.25 cm (0.5 inches) or greater. In an alternative embodiment, the porous element may have an inner tube concentric with its outer diameter.

The cross-sectional dimension of the cylinder may vary over a wide range. However, the cross-sectional dimension is generally critical to the performance of the cylinder for a given application, otherwise the dimensions of the cylinder are not critical and are dependent upon the carrier gas flow, the precursor compound to be used, the particular chemical vapor deposition system used and the like. The cross-sectional dimension determines, at a given pressure and flow rate, the linear velocity of the gas in the cylinder, which in turn controls the contact time between the precursor material and carrier gas and thus saturation of the carrier gas. Typically, the cylinder has a cross-sectional dimension of 5 cm (2 inches) to 15 cm (6 inches), and more typically 5 cm, 7.5 cm (3 inches), 10 cm (4 inches) or even greater. Cylinders having a cross-sectional dimension of less than 5 cm may also be suitably employed. The other dimensions for a particular cylinder are well within the ability of those skilled in the art. Exemplary cylinders are those marketed by Rohm and Haas Electronic Materials LLC (Marlborough, Massachusetts).

A source of solid organometallic precursor compound is contained within the inlet chamber. Such source of solid organometallic precursor is in the form of a frit having a substantially level surface. Any solid organometallic compound suitable for use in vapor delivery systems that may be fritted may be used in the present invention. As used herein, “fritting” refers to fusing the solid organometallic compound, such fused organometallic compound being gas-permeable. The solid organometallic compound is fritted under conditions that provide a frit of the solid organometallic compound having a substantially level top surface. In one embodiment, the frit of solid organometallic compound has a porosity gradient of progressively decreasing porosity from the top surface to a bottom surface of the frit. By “top surface” is meant the surface of the organometallic compound opposite the porous element.

Typically, the solid organometallic compound is first added to the inlet chamber of the cylinder, the cylinder is agitated to provide the solid organometallic compound with a substantially level surface, the solid organometallic compound is then fritted to form a frit of the solid organometallic compound. Such fritting step may optionally be performed with heating and is preferably performed with heating. In another embodiment, the agitation step may be performed with heating. Agitation may be performed by any suitable means, such as, but not limited to, tapping, vibration including vibration using electrostrictive or magnetostrictive transducers, pressurization, agitation by gas flow, agitation by liquid flow, rotation including the use of a rotating mixing chamber or a rotating stirrer, oscillation, stirring including using reciprocating stirrers, and shaking the cylinder to provide a level top surface of the organometallic compound. Combinations of such agitation methods may be used.

The heating step is performed at a temperature below the melting or decomposition temperature of the solid organometallic compound. Typically, the heating step is performed at a temperature of up to 5° C. below the melting or decomposition temperature of the solid organometallic compound, and more typically up to 10° C. below the melting or decomposition temperature of the solid organometallic compound. For example, TMI may be fritted at a temperature of 35-50° C. Such controlled heating may be performed using a water bath, an oil bath, hot air, a heating mantle and the like. The fritting step is performed for a period of time sufficient to fuse the solid organometallic compound into a frit. The time used for the fritting step depends on the particular solid organometallic compound used, the amount of the solid organometallic compound, and the particular temperature used, among other factors. In one embodiment, the fritting step is performed for 0.5 to 120 minutes, and typically from 1 to 60 minutes. Alternatively, the fritting step may be performed under lower-than-atmospheric pressure or alternatively under higher-than-atmospheric pressure.

A “frit of solid organometallic compound” refers to a fused cake of solid organometallic compound having a substantially level top surface and sufficient porosity to allow the carrier gas to pass through the cake. In general, when the frit of solid organometallic compound is first formed, it conforms to the internal dimensions of the cylinder, that is, the frit has a width substantially equal to the interior dimension of the inlet chamber. The height of the frit will depend upon the amount of solid organometallic compound used. The particular porosity will depend upon the fritting temperature used, the particular organometallic compound used and the particle size of the organometallic compound, among other factors. Smaller particles of solid organometallic compound will typically provide a frit of solid organometallic compound having smaller pores as compared to a frit formed from larger particles of the same solid organometallic compound. As used herein, “pore” refers to the space between particles of fused solid organometallic compound.

A desired particle size of the solid organometallic compound may be obtained by a variety of methods, such as, but not limited to, crystallization, grinding, and sieving. The solid organometallic compound may be dissolved in a solvent and crystallized by cooling, by the addition of a non-solvent or by both to provide the desired particles. Grinding may be performed manually, such as with a mortar and pestle, or by machine such as using a grinding mill. Particles of the solid organometallic compound may be sieved to provide solid organometallic compound having a substantially uniform particle size. Combinations of such methods may be employed to obtain organometallic compound in the desired particle size. In an alternative embodiment, solid organometallic compound having particles having different particle sizes may be used. The use of such different particle sizes may provide a frit of the solid organometallic compound having varying pore sizes.

In a further embodiment, the frit of the solid organometallic compound may contain a porosity gradient, i.e., a gradient of pore sizes. Such pore size gradient may be obtained by fritting a gradient of particles of the solid organometallic compound having varying sizes. Such gradient can be formed by sequentially adding particles of increasing (or decreasing) size to the cylinder; and agitating the cylinder to provide the solid organometallic compound with a level surface; and fritting the solid organometallic compound.

In yet another embodiment, the frit of the solid organometallic compound may contain regions of different pore sizes. For example, the frit may contain a region having a relatively large pore size, e.g. 5 μm, and a region having a relatively small pore size, e.g. 2 μm. There may be one or more of each region. When there are more than one of each region, such regions may be alternating. Additionally, there may be one or more other regions having yet different pore sizes.

Pore sizes in the frit of solid organometallic compound may also be controlled by using one or more of certain porosity forming aids, such as organic solvents or other removable agent. Any organic solvent that does not react with the organometallic compound may be used. Typical organic solvents include, without limitation, aliphatic hydrocarbons, aromatic hydrocarbons, amines, esters, amides, and alcohols. Such organic solvents do not need to, but may, dissolve the solid organometallic compound. In one embodiment, a slurry of the organometallic compound and solvent is added to a cylinder. A substantially level surface of the slurry is formed. The solvent is then removed and the solid organometallic compound is fritted. It will be appreciated by those skilled in the art that the solvent may be removed during the before, during or after the fritting step, and preferably before the fritting step. Typically, the average pore size in the frit of solid organometallic compound ranges from 0.05 to 500 μm, more typically from 0.1 to 250 μm, and still more typically from 0.5 to 100 μm.

Suitable solid organometallic compounds useful in the present invention include, without limitation: indium compounds, zinc compounds, magnesium compounds, aluminum compounds, gallium compounds, silicon compounds, carbon tetrabromide, metal beta-diketonates, and germanium compounds. Exemplary organometallic compounds include, without limitation: trialkyl indium compounds such as triethyl indium and trimethyl indium; trialkyl indium-amine adducts; dialkyl haloindium compounds such as dimethyl chloroindium; alkyl dihaloindium compounds such as methyl dichloroindium; cyclopentadienyl indium; trialkyl indium-trialkyl arsine adducts such as trimethyl indium-trimethyl arsine adduct; trialkyl indium-trialkyl-phosphine adducts such as trimethyl indium-trimethyl phosphine adduct; alkyl zinc halides such as ethyl zinc iodide; cyclopentadienyl zinc; ethylcyclopentadienyl zinc; alane-amine adducts; alkyl dihaloaluminum compounds such as methyl dichloroaluminum; alkyl dihalogallium compounds such as methyl dichlorogallium; dialkyl halogallium compounds such as dimethyl chlorogallium and dimethyl bromogallium; biscyclopentadienyl magnesium (“Cp₂Mg”); carbon tetrabromide; metal beta-diketonates, such as beta-diketonates of hafnium, zirconium, tantalum and titanium; silicon compounds, germanium compounds such as bis(bis(trimethylsilyl)amino) germanium and dipivolylmethanato-metallic (“DPM”) compounds. In the above organometallic compounds, the term “alkyl” refers to (C₁-C₆)alkyl. In one embodiment, the organometallic compound includes indium. Mixtures of organometallic precursor compounds may be used in the present delivery systems.

Any suitable carrier gas may be used with the present delivery device as long as it does not react with the organometallic precursor. The particular choice of carrier gas depends upon a variety of factors such as the organometallic precursor, the particular chemical vapor deposition system employed and the like. Suitable carrier gasses include, but are not limited to, hydrogen, nitrogen, argon, helium and the like. The carrier gas may be used with the present delivery device at a wide variety of flow rates. Such flow rates are a function of the cylinder cross-sectional dimension and pressure. Larger cross-sectional dimensions allow higher carrier gas flows, i.e. linear velocity, at a given pressure. For example, when the delivery device employs a cylinder has a 5 cm cross-sectional dimension, carrier gas flow rates of up to 500 sccm and greater may be used. The carrier gas flow entering the cylinder, exiting the cylinder or both entering and exiting the cylinder may be regulated by a control means. Any suitable control means may be used, such as manually activated control valves or computer activated control valves.

In use, the delivery device may be used at a variety of temperatures. The exact temperature will depend upon the particular precursor compound used and desired application. The temperature controls the vapor pressure of the precursor compound, which controls the flux of the material needed for specific growth rates or alloy compositions. Such temperature selection is well within the ability of one skilled in the art. For example, when the organometallic precursor compound is trimethyl indium, the temperature of the cylinder may be from 10° to 60° C. Other suitable temperature ranges include from 350 to 55°, and from 35° to 50° C. The present delivery devices may be heated by a variety of heating means, such as by placing the cylinder in a thermostatic bath, by direct immersion of the delivery device in a heated oil bath or by the use of a halocarbon oil flowing through a metal tube, such as a copper tube, surrounding the delivery device.

The carrier gas enters the cylinder inlet chamber through the inlet opening at the top of the cylinder. The carrier gas then passes through the frit of organometallic compound (precursor) and picks-up vaporized precursor to form a gas stream including vaporized precursor admixed with carrier gas. The amount of vaporized precursor picked-up by the carrier gas may be controlled. It is preferred that the carrier gas is saturated with vaporized precursor. The carrier gas is then directed to a porous element located at the floor of the inlet chamber. The carrier gas exits the inlet chamber through the porous element and enters the outlet chamber which is in fluid contact with the inlet chamber. The carrier gas then exits the outlet chamber through the outlet opening and is directed to a chemical vapor deposition system. The delivery devices of the present invention may be used with a variety of chemical vapor deposition systems.

Referring to the figures, like reference numerals refer to like elements. FIG. 1A illustrates a cross-sectional view of a prior art delivery device having a dual-fritted design and containing solid organometallic precursor. In this embodiment, an elongated cylindrical container 10 having an inner surface defining a substantially constant cross-section throughout the length of cylinder 10, a top closure portion 15 and a bottom closure portion 16 having a flat inner bottom portion. Top closure portion 15 has fill port 18, inlet opening 19 and outlet opening 20. Inlet tube 12 and outlet tube 13 communicate with inlet opening 19 and outlet opening 20, respectively, in closure portion 15 of the container. Carrier gas flow entering the container through inlet tube 12 and exiting the container through outlet tube 13 are regulated by control valves. The arrows indicate the direction of gas flow. The lower end of the inlet opening 19 communicates directly with inlet chamber 25. Inlet chamber 25 and outlet chamber 30 are in fluid communication by means of porous element 14 located in inlet chamber floor 9. Outlet opening 20 communicates with outlet chamber 30. A second porous element 33 is located at outlet opening 20. Solid organometallic compound 45 is located within inlet chamber 25, solid organometallic compound 45 having a surface 46 that is not substantially level.

Carrier gas enters the container through inlet tube 12 and into inlet chamber 25 containing the solid organometallic precursor 45. The carrier gas picks up the vaporized organometallic precursor to form a gas stream. The gas stream exits the inlet chamber 25 through porous element 14 and enters outlet chamber 30. The gas stream then passes through second porous element 33 and exits the outlet chamber 30 through outlet opening 20 into outlet tube 13 and then is directed into a chemical vapor deposition system. As solid organometallic compound 45 is depleted from the cylinder over time, the surface 46 of the solid organometallic compound gradually moves down the cylinder. However, surface 46 remains substantially non-level. Once any portion of surface 46 reaches porous element 14, an unobstructed path for the carrier gas through the inlet chamber is provided. See, for example, FIG. 1B. The carrier gas will follow this unobstructed path and will no longer pick up any solid organometallic compound 45. Thus, the cylinder is not fully depleted of solid organometallic compound.

FIG. 2 illustrates a cross-sectional view of a delivery device of the present invention having a non-annular design, and containing a frit of solid organometallic precursor compound. In this embodiment, an elongated cylindrical container 10 having an inner surface 11 defining a substantially constant cross-section throughout the length of cylinder 10, a top closure portion 15 and a bottom closure portion 16 having a flat inner bottom portion 17. Top closure portion 15 has fill port 18, inlet opening 19 and outlet opening 20. Inlet tube 12 and outlet tube 13 communicate with inlet opening 19 and outlet opening 20, respectively, in closure portion 15 of the container. Carrier gas flow entering the container through inlet tube 12 is regulated by control valve CV1. Carrier gas flow exiting the container through outlet tube 13 is regulated by control valve CV2. The lower end of the inlet opening 19 communicates directly with inlet chamber 25 having a center tube 31 concentric to its outer diameter and a conical shaped lower portion 21. Inlet chamber 25 and out let chamber 30 are in fluid communication by means of porous element 14. Porous element 14 is located at the tip or bottom of the conical section 21 of the inlet chamber. Outlet opening 20 communicates with outlet chamber 30 by means of center tube 31. A frit of solid organometallic compound 50, such as TMI, having substantially level surface 50 is located within inlet chamber 25.

Carrier gas enters the container through inlet tube 12 and into inlet chamber 25 containing the frit of solid organometallic precursor. The carrier gas picks up the vaporized organometallic precursor to form a gas stream. The gas stream exits the inlet chamber 25 through porous element 14 and enters outlet chamber 30. The gas stream then passes through center tube 31 and exits the outlet chamber 30 through outlet opening 20 into outlet tube 13 and then is directed into a chemical vapor deposition system.

FIG. 3 illustrates the cylinder of FIG. 1 except that inlet chamber 25 contains a frit of organometallic compound 50, such as tert-butyl germanium trichloride, having substantially level surface 55.

FIG. 4 illustrates a cross-sectional view of a delivery device of the present invention having an annular design and a conical-shaped lower portion and containing a frit of solid organometallic precursor compound. In this embodiment, an elongated cylindrical container 10 having an inner surface 11 defining a substantially constant cross-section throughout the length of cylinder 10, a top closure portion 15 and a bottom closure portion 16 having a flat inner bottom portion 17. Top closure portion 15 has fill port 18, inlet opening 19 and outlet opening 20. Inlet tube 12 and outlet tube 13 communicate with inlet opening 19 and outlet opening 20, respectively, in closure portion 15 of the container. Carrier gas flow entering the container through inlet tube 12 is regulated by control valve CV1. Carrier gas flow exiting the container through outlet tube 13 is regulated by control valve CV2. The lower end of the inlet opening 19 communicates directly with inlet chamber 25 having a conical shaped lower portion 21. Inlet chamber 25 and out let chamber 30 are concentric, inlet chamber 25 being located within outlet chamber 30, and in fluid communication by means of porous element 14. Porous element 14 is located at the tip or bottom of the conical section 21 of the inlet chamber. Outlet opening 20 communicates directly with outlet chamber 30. A frit of solid organometallic compound 50, such as dicyclopentadienyl magnesium, having substantially level surface 55 is located within inlet chamber 25.

Carrier gas enters the container through inlet tube 12 and into inlet chamber 25 containing the frit of solid organometallic precursor. The carrier gas picks up the vaporized organometallic precursor to form a gas stream. The gas stream exits the inlet chamber 25 through porous element 14 and enters outlet chamber 30. The gas stream then exits the outlet chamber 30 through outlet opening 20 into outlet tube 13 and then is directed into a chemical vapor deposition system.

Accordingly, the present invention provides a method of providing a fluid gas stream composed of a carrier gas saturated with organometallic compound to a chemical vapor deposition system including the steps of: a) providing a dual-chambered vessel having an elongated cylindrical shaped portion having an inner surface defining a substantially constant cross-section throughout the length of the cylindrical portion, a top closure portion, a bottom closure portion, and inlet and outlet chambers in fluid communication and separated by a porous element, the top closure portion having a fill plug and a gas inlet opening, the fill plug and gas inlet opening communicating with the inlet chamber, an outlet opening communicating with the outlet chamber, the porous element being spaced from the bottom closure portion, the porous element contained in a floor of the inlet chamber, and a frit of solid organometallic precursor contained within the inlet chamber; b) introducing a carrier gas into the inlet chamber through the gas inlet opening; c) flowing the carrier gas at a sufficient flow rate in contact with the frit of solid organometallic precursor to substantially saturate the carrier gas with the organometallic precursor; d) the precursor saturated carrier gas exiting from the inlet chamber through the porous element in the floor of the inlet chamber into the outlet chamber; and e) directing the precursor saturated carrier gas to exit the outlet chamber through the outlet opening.

The chemical vapor deposition systems includes a deposition chamber, which is typically a heated vessel within which is disposed at least one, and possibly many, substrates. The deposition chamber has an outlet, which is typically connected to a vacuum pump in order to draw by-products out of the chamber and to provide a reduced pressure where that is appropriate. MOCVD can be conducted at atmospheric or reduced pressure. The deposition chamber is maintained at a temperature sufficiently high to induce decomposition of the vaporized precursor compound. The typical deposition chamber temperature is from 300° to 1000° C., the exact temperature selected being optimized to provide efficient deposition. Optionally, the temperature in the deposition chamber as a whole can be reduced if the substrate is maintained at an elevated temperature, or if other energy such as radio frequency (“RF”) energy is generated by an RF source.

Suitable substrates for deposition, in the case of electronic device manufacture, may be silicon, gallium arsenide, indium phosphide, and the like. Such substrates are particularly useful in the manufacture of electronic devices such as light emitting diodes and integrated circuits.

Deposition is continued for as long as desired to produce a metal film having the desired properties. Typically, the film thickness will be from several hundred to several thousand angstroms or more when deposition is stopped.

Also provided by the present invention is a method of depositing a metal film including the steps of: a) providing a dual-chambered vessel having an elongated cylindrical shaped portion having an inner surface defining a substantially constant cross-section throughout the length of the cylindrical portion, a top closure portion, a bottom closure portion, and inlet and outlet chambers in fluid communication and separated by a porous element, the top closure portion having a fill plug and a gas inlet opening, the fill plug and gas inlet opening communicating with the inlet chamber, an outlet opening communicating with the outlet chamber, the porous element being spaced from the bottom closure portion, the porous element contained in a floor of the inlet chamber, and a frit of solid organometallic precursor contained within the inlet chamber; b) introducing a carrier gas into the inlet chamber through the gas inlet opening; c) flowing the carrier gas at a sufficient flow rate in contact with the frit of solid organometallic precursor to substantially saturate the carrier gas with the organometallic precursor; d) the precursor saturated carrier gas exiting from the inlet chamber through the porous element in the floor of the inlet chamber into the outlet chamber; e) directing the precursor saturated carrier gas to exit the outlet chamber through the outlet opening; f) delivering the precursor saturated carrier gas to a reaction vessel containing a substrate; and g) subjecting the precursor saturated carrier gas to conditions sufficient to decompose the precursor to form a metal film on the substrate.

While the present invention may be used at a variety of system pressures, an advantage of the present invention is that higher depletion rates, higher flow rates, lower pressures or a combination of higher flow rates and lower pressures may be used. The delivery devices of the present invention have the additional advantage of providing uniform carrier gas flow through the frit of solid organometallic precursor.

### EXAMPLE 1

TMI (175 g) was added to a 5 cm diameter cylinder. The TMI was ground to a fine powder prior to addition to then cylinder. The cylinder was agitated by tapping the cylinder on a hard surface at room temperature to provide a substantially level surface. After the substantially level surface was obtained, the TMI was fused by heating at approximately 45° C. for 1 hour, followed by cooling to form a frit of the TMI.

A testing apparatus including a mass flow controller, pressure controller, EPISON™ III ultrasonic monitor, constant temperature bath, vacuum pump and associated valves and piping was constructed to measure flow stability and saturated vapor flow. The EPISON™ III ultrasonic monitor was used to determine the TMI gas phase concentrations, while an MKS model 640A pressure controller and MKS model 1179A mass flow controller monitored by an MKS model 247B readout provided the carrier gas at a constant pressure and flow rate. The cylinder was installed in the system. The constant temperature bath was maintained at 30° C., the system pressure maintained at 600 torr (800 mbar), and a hydrogen carrier gas flow was maintained at 400 sccm, which provided a TMI concentration of 0.435% in the vapor phase. A stable concentration of TMI vapor in hydrogen was maintained for 175 hours, as measured by the ultrasonic monitor. This allowed the cylinder to reach ≧75% depletion.

### EXAMPLE 2

TMI is first ground to a substantially uniform size of 3-4 mm. A constant particle size will be ensured by passing the TMI powder though precision sieves. Material that passes a #5 sieve but is retained in a #7 sieve is transferred to a cylinder and the procedure of Example 1 is repeated. Results are expected to be similar to those of Example 1.

### EXAMPLE 3

TMI is first ground and is then passed through precision sieves to provide two portions of TMI, each having a different particle size. Portion 1 is obtained by collecting TMI particles using #8 and #10 sieves. The particles of Portion 1 have a size range of 2-2.35 mm. Portion 2 is obtained by collecting TMI particles using and #45 and #70 sieves. The particles of Portion 2 have sizes of 0.212-0.355 mm. Equal amounts of Portions 1 and 2 are then mixed, and the mixture is then introduced into a cylinder. This cylinder is then used to repeat the procedure of Example 1. Results are expected to be similar to those of Example 1.

### EXAMPLE 4

The procedure of Example 3 is repeated except that Portions 1 and 2 are introduced to the cylinder in alternating layers rather than as a mixture. Results are expected to be similar to those of Example 1.

### EXAMPLE 5

The procedure of example 4 is repeated except that bis(cyclopentadienyl)magnesium is used instead of TMI. Stable concentrations of magnesium are expected in the vapor phase for over 100 hours using flow and pressure conditions similar to those in Example 1.

### EXAMPLE 6

The procedure of example 1 is repeated except that carbon tetrabromide is used instead of TMI. Stable concentrations of carbon in the vapor phase are expected at 25° C. for over 100 hours using flow and pressure conditions similar to those in Example 1.

### EXAMPLE 7

The procedure of example 1 is repeated except the constant temperature bath is maintained at 17° C., the system pressure is maintained at 300 torr (400 mbar), and a hydrogen carrier gas flow is maintained at 600 sccm. A stable concentration of trimethylindium vapor in hydrogen is expected to be maintained for over 200 hours, as measured by the ultrasonic monitor.

### EXAMPLE 8

### Comparative

The procedure of Example 1 was repeated except that the cylinder was maintained at room temperature prior to testing, and the TMI was not fritted. The delivery of TMI was found to be stable during the initial stages and for up to 140 hours, which represented approximately 57% depletion of the cylinder contents.

What is claimed is:

1. A vapor-phase delivery apparatus for solid organometallic compounds comprising a dual-chambered vessel having an elongated cylindrical shaped portion having an inner surface, a top closure portion, a bottom closure portion, and inlet and outlet chambers in fluid communication and separated by a porous element, the top closure portion having a fill plug and a gas inlet opening, the fill plug and gas inlet opening communicating with the inlet chamber, an outlet opening communicating with the outlet chamber, the porous element being spaced from the bottom closure portion, the porous element contained in a floor of the inlet chamber, and a frit formed from solid organometallic precursor contained within the inlet chamber.

2. The vapor phase delivery device of claim 1 wherein the solid organometallic compound is chosen from: trialkyl indium compounds; trialkyl indium-amine adducts; dialkyl haloindium compounds; alkyl dihaloindium compounds; cyclopentadienyl indium; trialkyl indium-trialkyl arsine adducts; trialkyl indium-trialkyl-phosphine adducts; alkyl zinc halides; cyclopentadienyl zinc; ethylcyclopentadienyl zinc; alkyl dihaloaluminum compounds; alane-amine adducts; alkyl dihalogallium compounds; dialkyl halogallium compounds; biscyclopentadienyl magnesium; silicon compounds; germanium compounds; carbon tetrabromide; and metal beta-diketonates.

3. The vapor phase delivery device of claim 1 wherein the frit has sufficient porosity to allow the carrier gas to pass through.

4. The vapor phase delivery device of claim 3 wherein the frit has a porosity gradient.

5. The vapor phase delivery device of claim 3 wherein the frit has regions of differing porosity.

6. A method of depositing a metal film comprising the steps of: a) providing the vapor-phase delivery apparatus of claim 1; b) introducing a carrier gas into the inlet chamber through the gas inlet opening; c) flowing the carrier gas at a sufficient flow rate in contact with the source of solid organometallic precursor to substantially saturate the carrier gas with the organometallic precursor; d) directing the precursor saturated carrier gas to exit the vapor-phase delivery apparatus through the outlet opening; f) delivering the precursor saturated carrier gas to a reaction vessel containing a substrate; and g) subjecting the precursor saturated carrier gas to conditions sufficient to decompose the precursor to form a metal film on the substrate.

7. A method of forming the vapor phase delivery device of claim 1 comprising the steps of: a) providing a vapor-phase delivery apparatus having a dual-chambered vessel having an elongated cylindrical shaped portion having an inner surface, a top closure portion, a bottom closure portion, and inlet and outlet chambers in fluid communication and separated by a porous element, the top closure portion having a fill plug and a gas inlet opening, the fill plug and gas inlet opening communicating with the inlet chamber, an outlet opening communicating with the outlet chamber, the porous element being spaced from the bottom closure portion, the porous element contained in a floor of the inlet chamber; b) introducing solid organometallic precursor to the vapor-phase delivery apparatus; c) agitating the vapor-phase delivery apparatus to provide the solid organometallic precursor with a level surface; and d) fritting the solid organometallic precursor.

8. The method of claim 7 wherein the solid organometallic precursor in step b) comprises one or more porosity forming aids.

9. The method of claim 7 wherein step d) comprises heating.
